(19) United States
(12) Patent Application Publication
(10) Pub. No.: US 2023/0029076 A1
(43) Pub. Date: Jan. 26, 2023

(54) FAN ASSEMBLY AND INVERTER

(71) Applicant: Sungrow Power Supply Co., Ltd., Hefei (CN)

(72) Inventors: Xin Yang, Hefei (CN); Jie Zhou, Hefei (CN); Qi Yao, Hefei (CN)

(73) Assignee: Sungrow Power Supply Co., Ltd., Hefei (CN)

(21) Appl. No.: 17/862,897

(22) Filed: Jul. 12, 2022

(30) Foreign Application Priority Data
Jul. 13, 2021 (CN) 202110790364.4

(51) Int. Cl. F04D 29/66; H05K 7/20; F04D 19/00; F04D 29/64

(52) U.S. Cl. CPC F04D 29/668; H05K 7/20909; F04D 19/002; F04D 29/646

(57) ABSTRACT

A fan assembly and an inverter are provided. The fan assembly includes a fan guard, a fan body and a noise reduction mounting member. The fan body directly faces an air inlet, the air inlet is covered by a fan guard, and the noise reduction mounting member is arranged on the fan body, to provide a preset distance between the fan body and the fan guard, and the noise reduction mounting member is configured to mount the fan body on a to-be-mounted component in a buffered manner. The distance between the fan body and the fan guard can reach the preset distance due to the noise reduction mounting member. In addition, the noise reduction mounting member plays a vibration isolation function between the fan body and the to-be-mounted component, which improves the sound quality.

### CROSS REFERENCE TO RELATED APPLICATIONS

This application claims the priorities to Chinese patent application No. 202110790364.4, titled “FAN ASSEMBLY AND INVERTER”, filed with the China National Intellectual Property Administration Jul. 13, 2021, the entire disclosure of which is hereby incorporated by reference.

### FIELD

The present application relates to the technical field of heat dissipation for inverters, and in particular to a fan assembly and an inverter.

### BACKGROUND

Since the power of inverters is required to be greater and greater while the volume is required to be smaller and smaller, the heat dissipation of the inverter worsens. Therefore, the performance of the fan assembly is required to be continuously improved, and the air volume of the fan assembly needs to be increased, hence the rotation speed of the fan assembly is higher and higher. However, the increase of the wind speed may increase the fundamental frequency vibration of the fan assembly, resulting in deterioration of the noise and reduction of the sound quality.

Currently, the conventional method for mounting the fan assembly is generally to directly fix a fan body onto a to-be-mounted component through a screw, and mount a fan guard on the fan body. The disadvantage of this method is that the vibration of this structure may be intensified after the rotation speed of the fan body increases, which is very easy to excite the natural frequency of the member in contact with the structure, thus the resonance is formed and the vibration generated by the rotation of the fan assembly is increased. In addition, since the fan body and the fan guard are mounted close to each other, when the fan body rotates at a high speed, the air flows through the fan guard and forms a high-order vortex, which increases the aerodynamic noise and the noise generated by the rotation of the fan assembly.

### SUMMARY

An object according to the present application is to provide a fan assembly, which can not only prevent the resonance from being formed between a fan body and a to-be-mounted component (e.g., a fan bracket), but also reduce aerodynamic noises and improve sound quality.

Another object according to the present application is to provide an inverter using the fan assembly, which can not only prevent the resonance from being formed between the fan body and the to-be-mounted component, but also reduce the aerodynamic noise and improve the sound quality under the condition of ensuring efficient heat dissipation of the inverter.

In order to achieve the above objects, the following technical solutions are provided according to the present application.

A fan assembly includes a fan body and a noise reduction mounting member, the fan body is arranged to directly face an air inlet, and the air inlet is covered by a fan guard; the noise reduction mounting member is arranged at the fan body, to provide a preset distance between the fan body and the fan guard, and the noise reduction mounting member is configured to mount the fan body to a to-be-mounted component in a buffered manner.

In an embodiment, the fan assembly further includes a fan bracket, where the air inlet is provided on the fan bracket, and the noise reduction mounting member is configured to mount the fan body and the fan guard at the fan bracket in a buffered manner.

In an embodiment, the noise reduction mounting member includes a vibration damper arranged between the fan guard and the fan body, and the vibration damper is fixed on the fan bracket; and a fastener configured to connect the fan guard, the vibration damper and the fan body with each other.

In an embodiment, the vibration damper includes:

a vibration damping pad fixed on the fan bracket, where a through hole is provided in the vibration damping pad;

a bushing arranged in the through hole of the vibration damping pad; and

a gasket arranged on the bushing, where the fastener passes through the fan guard, the gasket, the bushing and the fan body successively to connect the fan guard, the gasket, the bushing and the fan body with each other.

In an embodiment, a clamping groove is circumferentially provided on an outer periphery of the vibration damping pad, and the fan bracket is clamped and fixed in the clamping groove.

In an embodiment, the vibration damping pad is a rubber pad or a spring.

In an embodiment, a height of the vibration damper is greater than or equal to 10 mm.

In an embodiment, the noise reduction mounting member further includes a nut screwed on the fastener and abutting against the fan body.

In an embodiment, the fan body is integrally formed with the noise reduction mounting member.

In an embodiment, multiple noise reduction mounting members are provided, and the multiple noise reduction mounting members are arranged spaced apart along a circumferential direction of the fan body.

In an embodiment, multiple fan bodies are provided, and the multiple fan bodies are arranged spaced apart on the fan bracket.

An inverter includes the fan assembly according to the above solutions.

In an embodiment, the inverter further includes a box and heat dissipation fins arranged on the box, where the fan assembly is arranged to directly face the heat dissipation fins, and the fan assembly is configured to dissipate heat for the heat dissipation fins.

The beneficial effects according to the present application are as follows.

The fan assembly is provided according to the present application, which includes the fan guard, the fan body and the noise reduction mounting member. The fan body is arranged to directly face the air inlet, the fan guard covers the air inlet, so as to ensure air circulation. The noise reduction mounting member is arranged at the fan body, to provide the preset distance between the fan body and the fan guard, so as to prevent the fan body and the fan guard from being mounted close to each other, the distance between the fan body and the fan guard is increased, which avoids the formation of high-order vortex when the air flows through the fan guard, thereby reducing the aerodynamic noise and improving the sound quality. In addition, the noise reduction mounting member can mount the fan body on the to-be-mounted component in a buffered manner, so that the noise reduction mounting member plays a vibration isolation function between the fan body and the to-be-mounted component, the energy generated by the vibration of the fan body is dissipated by the noise reduction mounting member, thus the excitation of the fan body on the to-be-mounted component becomes small, which increases the loss in transmission of the vibration of the fan body, thereby reducing the noise caused by the vibration of the fan body and improving the sound quality.

The inverter employing the fan assembly is provided according to the present application, which can not only avoid the formation of resonance between the fan body and the to-be-mounted component, but also reduce the aerodynamic noise and improve the sound quality under condition of ensuring efficient heat dissipation of the inverter.

### BRIEF DESCRIPTION OF THE DRAWINGS

FIG. 1 is a schematic view showing the structure of an inverter according to a first embodiment of the present application;

FIG. 2 is a schematic view showing the structure of a fan assembly according to the first embodiment of the present application;

FIG. 3 is a cross-sectional view of part of the fan assembly according to the first embodiment of the present application;

FIG. 4 is an exploded view of the fan assembly provided according to the first embodiment of the present application;

FIG. 5 is a partially enlarged view of portion A in FIG. 3;

FIG. 6 is a schematic view showing the structure of a vibration damping pad according to the first embodiment of the present application; and

FIG. 7 is a schematic view of a fan body and a vibration damping pad according to a second embodiment of the present application.

### REFERENCE NUMERALS

| | | | |
|---|---|---|---|
| 100 | fan assembly; | 200 | box; |
| 300 | heat dissipation fin; | 1 | fan bracket; |
| 11 | air inlet; | 12 | third mounting hole; |
| 2 | fan guard; | 21 | first mounting hole; |
| 3 | fan body; | 31 | second mounting hole; |
| 4 | noise reduction mounting member; | 41 | vibration damper; |
| 411 | vibration damping pad; | 4111 | through hole; |
| 4112 | clamping groove; | 412 | bushing; |
| 413 | gasket; | 42 | fastener; |
| 43 | nut. | | |

### DETAILED DESCRIPTION OF THE EMBODIMENTS

In order to make the technical problems solved by the present application, the technical solutions adopted and the technical effects achieved more clear, the technical solutions of the present application will be further explained below in conjunction with the drawings and embodiments.

In the description of the present application, it should be pointed out that, terms “link”, “connect” and “fix” should be understood broadly, unless otherwise specifically defined. For example, it may be fixedly connected or detachably connected or integrally connected; it may be mechanically connected or electrically connected; it may be directly connected or indirectly connected through an intermediate media, or mutual connection between insides of two components, or the interaction relationship between the two components. For those skilled in the art, the specific meaning of the above terms in the present application should be understood in the light of specific circumstances.

In the present application, unless otherwise specified and limited, the first feature being “on” or “under” the second feature may include direct contact between the first and second features, and may also include that the first and second features are not in direct contact but in indirect contact through another feature between them. Furthermore, the first feature being “above”, “over” and “on” the second feature includes that the first feature is directly above and obliquely above the second feature, or simply indicates that a level of the first feature is higher than that of the second feature. The first feature being “below”, “under” and “down” the second feature includes that the first feature is directly below and obliquely below the second feature, or simply means that the level of the first feature is lower than that of the second feature.

In the description of the present application, the orientation or positional relationships indicated by terms “up”, “down”, “left”, “right” and the like are based on the orientation or positional relationships shown in the drawings, and are merely for the convenience of describing the present application and the simplification of the description, which do not indicate or imply that the device or element referred to must be in a particular orientation, or be constructed and operated in a particular orientation, and therefore should not be construed as a limit to the scope of the present application. In addition, the terms “first” and “second” are only used to distinguish them in description, which have no special meaning.

### First Embodiment

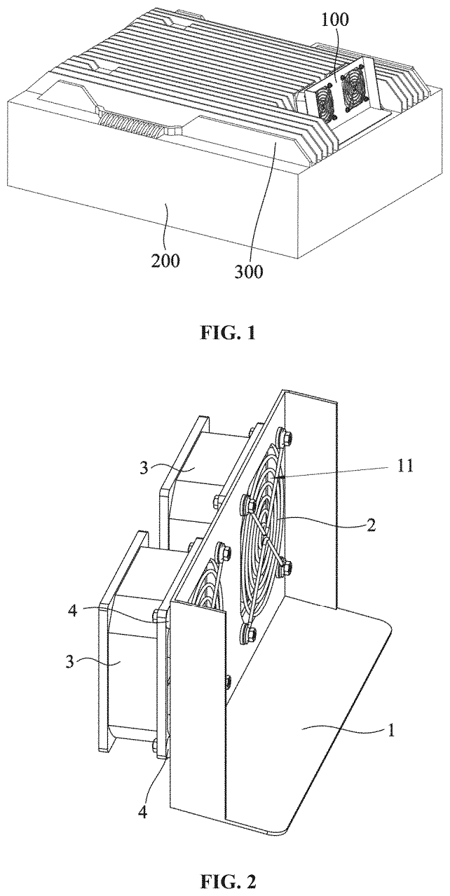

As shown in FIG. 1, a fan assembly 100 is provided according to this embodiment, the fan assembly 100 is generally used to dissipate heat for an inverter, but is not limited to this, and it may also be used to dissipate heat for other devices.

Specifically, as shown in FIG. 2, the fan assembly 100 according to this embodiment includes a fan bracket 1, a fan guard 2 and a fan body 3. An air inlet 11 is provided in the fan bracket 1, the fan guard 2 is configured to cover the air inlet 11, the fan body 3 is mounted on the fan bracket 1 and is arranged to directly face the air inlet 11, the fan guard 2 can ensure the circulation of air at the air inlet 11 and can also protect the fan body 3, to prevent foreign matters from entering the fan body 3 and causing danger, and avoid accidental touch of the fan body 3, thereby ensuring personal safety. The fan body 3 rotates so that the air passes through the fan guard 2 from the air inlet 11 to realize air circulation and realize ventilation and heat dissipation.

However, the conventional method for mounting the fan assembly 100 is generally to directly fix the fan body 3 on the fan bracket 1 through a screw. The disadvantage of this method is that the vibration of this structure may be intensified after the rotation speed of the fan body 3 increases, which is very easy to excite the natural frequency of the member in contact with the structure, thus the resonance is formed and the vibration generated by the rotation of the fan assembly 100 is increased. In addition, since the fan body 3 and the fan guard 2 on the fan bracket 1 are mounted close to each other, when the fan body 3 rotates at a high speed, the air flows through the fan guard 2 and forms a high-order vortex, which increases the aerodynamic noise and the noise generated by the rotation of the fan assembly 100.

In order to solve the above problems, as shown in FIG. 2, the fan assembly 100 according to the present application includes a noise reduction mounting member 4, the noise reduction mounting member 4 is arranged at the fan body 3, to provide a preset distance between the fan body 3 and the fan guard 2, so as to prevent the fan body 3 and the fan guard 2 from being mounted close to each other, the distance between the fan body 3 and the fan guard 2 is increased, which avoids the formation of high-order vortex when the air flows through the fan guard 2, thereby reducing the aerodynamic noise and improving the sound quality.

In addition, the noise reduction mounting member 4 can mount the fan body 3 on the fan bracket 1 in a buffered manner, so that the noise reduction mounting member 4 plays a vibration isolation function between the fan body 3 and the fan bracket 1, the energy generated by the vibration of the fan body 3 is dissipated by the noise reduction mounting member 4, the excitation of the fan body 3 on the fan bracket 1 becomes small, which increases the loss in transmission of the vibration of the fan body 3, thereby reducing the noise caused by the vibration of the fan body 3 and improving the sound quality.

Preferably, as shown in FIG. 2, multiple noise reduction mounting members 4 are provided, and the multiple noise reduction mounting members 4 are arranged spaced apart along a circumferential direction of the fan body 3, which can not only ensure the stable mounting between the fan body 3 and the fan bracket 1, but also further increase the consumption of energy generated by the vibration of the fan body 3, and thereby improving the sound quality.

An inverter employing the fan assembly 100 is provided according to the present application, which can not only avoid the formation of the resonance between the fan body 3 and the fan bracket 1, but also reduce the aerodynamic noise and improve the sound quality under condition of ensuring efficient heat dissipation of the inverter.

In this embodiment, as shown in FIG. 1, the inverter further includes a box 200 and heat dissipation fins 300. The heat dissipation fins 300 are arranged on the box 200, which can dissipate heat for elements inside the box 200, to ensure the normal operation of the inverter. The fan assembly 100 is arranged to directly face the heat dissipation fins 300, and the fan assembly 100 is used to dissipate heat for the heat dissipation fins 300, so as to further improve the heat dissipation effect of the heat dissipation fins 300 for the elements inside the inverter. Specifically, the fan assembly 100 is arranged to directly face to air ducts on the heat dissipation fins 300, which can accelerate the air circulation on the heat dissipation fins 300, and thereby improving the heat dissipation effect of the fan assembly 100 on the heat dissipation fins 300.

Specifically, as shown in FIG. 1 and FIG. 2, the fan bracket 1 is L-shaped, one side wall of the fan bracket 1 is fixed to the box 200, another sidewall of the fan bracket 1 is configured to mount the fan body 3 and the fan guard 2, so that the fan body 3 is arranged to directly face the air ducts on the heat dissipation fins 300. The fan bracket 1 is designed to be L-shaped, which not only increases a mounting area between the fan bracket 1 and the box 200 to ensure that the fixing between the fan assembly 100 and the box 200 is more stable, but also is beneficial to ensuring that the fan body 3 and the air ducts on the heat dissipation fins 300 are arranged to directly face each other, to ensure the heat dissipation effect.

It should be noted that in other embodiments, the fan assembly 100 may also be mounted on the heat dissipation fins 300 in a manner that the fan assembly 100 directly faces the heat dissipation fins 300, so as to ensure the heat dissipation effect of the heat dissipation fins 300.

Preferably, as shown in FIG. 1 and FIG. 2, multiple fan bodies 3 are provided, the multiple fan bodies 3 are arranged spaced apart on the fan bracket 1, and the multiple fan bodies 3 are arranged spaced apart along a distribution direction of the heat dissipation fins 300, so as to further improve the heat dissipation effect of the fan assembly 100 on the heat dissipation fins 300, and ensure the normal operation of the inverter.

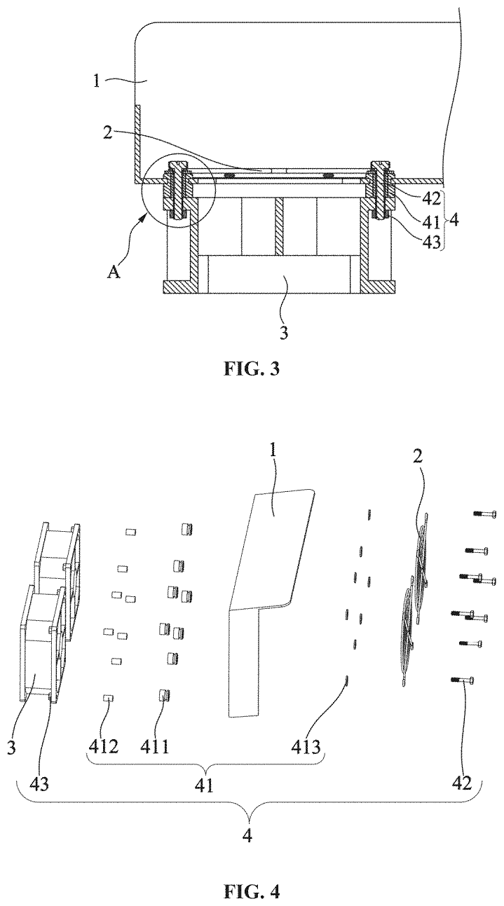

The specific structure of the noise reduction mounting member 4 is illustrated in conjunction with FIG. 3 and FIG. 4. As shown in FIG. 3 and FIG. 4, the noise reduction mounting member 4 includes a vibration damper 41 and a fastener 42, the vibration damper 41 is arranged between the fan guard 2 and the fan body 3, the vibration damper 41 is fixed on the fan bracket 1, and the fastener 42 is configured to connect the fan guard 2, the vibration damper 41 and the fan body 3 with each other. This arrangement can ensure the buffered mounting between the fan bracket 1 and the fan body 3, so that the energy generated by the vibration of the fan body 3 is dissipated by the vibration damper 41. The fastener 42 can pass through the fan guard 2, the vibration damper 41 and the fan body 3 successively to connect the fan guard 2, the vibration damper 41 and the fan body 3 with each other, which can avoid the problem of resonance of the fastener 42 to a certain extent. Specifically, the fastener 42 may be a bolt, which can realize the detachable mounting between the fan guard 2, the vibration damper 411 and the fan body 3. The bolt also has the advantages of high reliability and low cost.

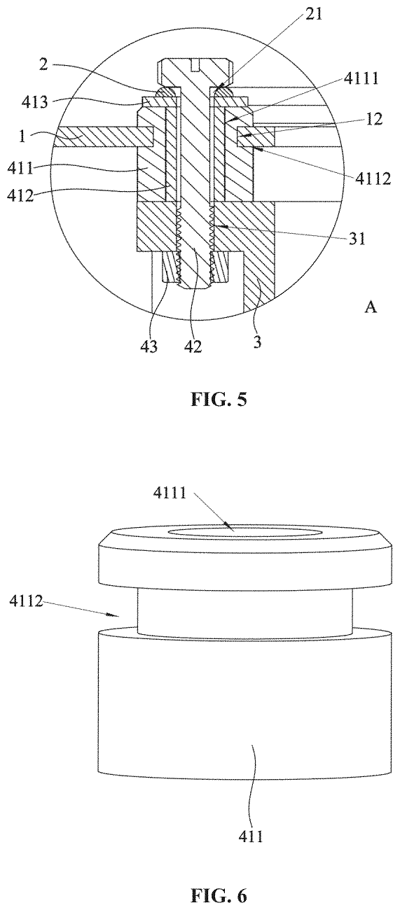

Preferably, as shown in FIG. 4 and FIG. 5, the vibration damper 41 includes a vibration damping pad 411, a bushing 412 and a gasket 413. The vibration damper 41 is fixed on the fan bracket 1, a through hole 4111 is provided inside the vibration damping pad 411, the bushing 412 is arranged in the through hole 4111 of the vibration damping pad 411, the gasket 413 is arranged on the bushing 412, and the fastener 42 passes through the fan guard 2, the gasket 413, the bushing 412 and the fan body 3 successively to connect the fan guard 2, the gasket 413, the bushing 412 and the fan body 3 with each other. The bushing 412 and the gasket 413 are provided, which can not only ensure the stable connection of the fastener 42 with the fan guard 2 and the fan body 3, to ensure the tightness of the assembly, but also further improve the vibration damping effect of the vibration damper 41, to realize consumption of the vibration of the fan body 3 through multi-layer buffering.

Furthermore, as shown in FIG. 5 and FIG. 6, a clamping groove 4112 is circumferentially provided on an outer periphery of the vibration damping pad 4111, and the fan bracket 1 is clamped and fixed in the clamping groove 4112, which can not only ensure that the vibration damping pad 411 be more firmly clamped on the fan bracket 1, but also increase a contact area between the vibration damping pad 411 and the fan bracket 1, and further increase the anti-vibration and vibration-absorbing effect of the vibration damping pad 411.

Specifically, as shown in FIG. 5, a first mounting hole 21 is provided in the fan guard 2, a second mounting hole 31 is provided in the fan body 3, and the fastener 42 passes through the first mounting hole 21, the gasket 413, the bushing 412 and the second mounting hole 31 successively to connect the fan guard 2 with the fan body 3. The above connection mode has the advantages of compact structure, ingenious design and easy mounting. It should be noted that in this embodiment, a third mounting hole 12 is provided in the fan bracket 1, and the vibration damping pad 411 passes through the third mounting hole 12 and is clamped and fixed in the third mounting hole 12 through the clamping groove 4112.

Preferably, the vibration damping pad 411 is a rubber pad, which has certain elasticity, good vibration damping effect and vibration-absorbing effect, in addition, the rubber pad has a stable structure, is not easy to damage and has low cost. It should be noted that in other embodiments, the vibration damping pad 411 may be a spring, which has good elasticity and low cost.

In order to ensure the reliable mounting of the fastener 42, as shown in FIG. 5, the noise reduction mounting member 4 further includes a nut 43, which is screwed on the fastener 42 and abuts against the fan body 3, so as to prevent the fastener 42 from falling off and ensure a more stable and reliable connection. It should be noted that the second mounting hole 31 is a threaded hole, so as to ensure the reliability of the fastener 42.

Preferably, in this embodiment, the preset distance between the fan body 3 and the fan guard 2 is greater than or equal to 10 mm, with this preset distance, the generation of high-order vortex noise of the fan body 3 can be avoided, which effectively reduces the aerodynamic noise of the fan body 3 and improves the sound quality.

The principle of obtaining the preset distance is described hereinafter. For the vortex formed by the air flowing through the fan guard 2, a sound pressure equation considering only the influence of a dipole source is as follows.

$$p ( x , t ) = \frac{1}{4 π} \int {\int }_{V} \int \frac{1}{r} [ - \frac{\partial {F}_{i}}{\partial {y}_{i}} ] dV ( y , τ )$$

Where, p is a sound pressure, r is a distance from a coordinate origin to a point in the sound source field, Fi is a pulse force per unit volume, x is a position vector of a field point, y is a position vector of a source point, and τ is a delay time. In order to obtain the explicit relationship between the sound pressure p and aerodynamic force in sound source field, Hemholz equation is introduced:

$$\int {\int }_{V} \int \frac{\partial {F}_{i}}{\partial {y}_{i}} ℊ ( x , y , ω ) dV = - \int {\int }_{V} \int {F}_{i} \frac{\partial ℊ ( x , y , ω )}{\partial {y}_{i}} dV$$

A far-field frequency-domain sound pressure formula of the fan body 3 under cylindrical coordinate system is derived from the above formulas:

$$p ( x , ω ) = {\sum }_{n = - ∞}^{+ ∞} \frac{ik \cdot {e}^{ikor}}{4 π r} \int {\int }_{s} F ( R , {θ}_{b} , ω ) cos γ cos β Jn ( {K}_{0} R ε \cdot β ) {e}^{in ( \frac{π}{2} + {θ}_{b} - α )} dS$$

Further, a sound pressure spectral density function can be obtained as follows:

$$φ = \frac{{k}_{0}^{2} cos β \cdot cos γ}{16 {π}^{2} {r}^{2}} Φ$$

Where, Φ is an autopower spectral density function of the whole sound source, k0=ω/a₀ (a₀ is the sound velocity, ω is the circular frequency), β is the angle of the field point in cylindrical coordinates, and γ is an average mounting angle of blades. It can be seen from the sound pressure spectral density function that the sound pressure spectral density is inversely proportional to the square of the distance between the vortex generated by the fan guard 2 and the blades on the fan body 3. The smaller the distance is, the greater the sound pressure spectral density is (that is, the greater the noise is). The greater the distance is, the smaller the sound pressure spectral density is. When the distance reaches a certain value, the sound pressure spectral density tends to become a stable value. Therefore, in this embodiment, based on this principle and combined with the experiments, it is established that the preset distance between the fan body 3 and the fan guard 2 is greater than or equal to 10 mm.

In order to ensure that the preset distance between the fan body 3 and the fan guard 2 is greater than or equal to 10 mm, a height of the vibration damper 41 is greater than or equal to 10 mm. It should be noted in this embodiment that, since a thickness of the gasket 413 is negligible, it is only necessary to ensure that a height of the bushing 412 is greater than or equal to 10 mm.

Since a size of the fan assembly 100 is directly related to a weight of the fan assembly 100, and a natural frequency of the fan assembly 100 is negatively correlated with the weight of the fan assembly 100, that is, the larger the size of the fan assembly 100 is, the greater the weight is, the lower the natural frequency of the fan assembly 100 is, and the easier it is to excite the lower-order natural frequency of the fan assembly 100. In addition, in a case that the specification of the fan assembly 100 is different, the wind speed at the air inlet 11 is different, and the flow field characteristics at the air inlet 11 are also different. If the distance between the fan body 3 and the fan guard 2 at the air inlet 11 is kept unchanged, the greater the wind speed at the air inlet 11 is, the greater the vortex noise is. Therefore, the height of the vibration damper 41 according to this embodiment can be adjusted according to the size and specification of the fan body 3 on the fan assembly 100, so as to ensure that the vibration damper 41 can avoid the generation of high-order vortex noise and reduce the aerodynamic noise for the fan assembly 100 of different sizes or specifications.

### Second Embodiment

The structure of the fan assembly 100 in this embodiment is substantially the same with that in the first embodiment. The difference between the fan assembly 100 in this embodiment and the fan assembly in the first embodiment is that the fan body 3 is integrally formed with the noise reduction mounting member 4.

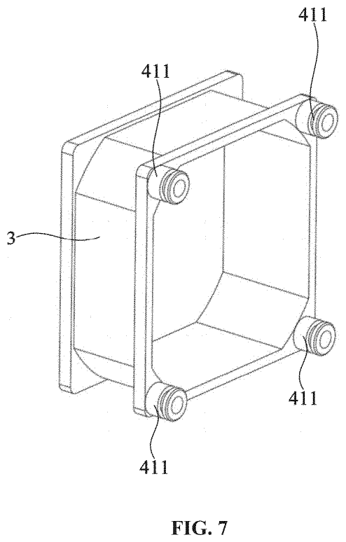

Specifically, as shown in FIG. 7, the fan body 3 and the vibration damping pad 411 are integrally formed, which improves the connection stability between the fan body 3 and the vibration damping pad 411, and facilitates the mounting of the fan body 3 on the fan bracket 1, which only requires to clamp the clamping groove 4112 of the vibration damping pad 411 into the third mounting hole 12.

Obviously, the above embodiments of the present application are merely examples for clear illustration of the present application, which are not intended to limit the implementation of the present application. For those skilled in the art, other changes or modifications in different forms may be made on the basis of the above illustration. It is unnecessary and impossible to list all the implementations here. Any modification, equivalent substitution, or improvement made within the principle of the present application shall fall within the protection scope of the claims of the present application.

1. A fan assembly, comprising:
a fan body and a noise reduction mounting member; wherein
the fan body is arranged to directly face an air inlet, and the air inlet is covered by a fan guard; and
the noise reduction mounting member is arranged at the fan body, to provide a preset distance between the fan body and the fan guard, and the noise reduction mounting member is configured to mount the fan body at a fan bracket in a buffered manner.

2. The fan assembly according to claim 1, further comprising:
the fan bracket, wherein the air inlet is provided on the fan bracket, and the noise reduction mounting member is configured to mount the fan body and the fan guard at the fan bracket in a buffered manner.

3. The fan assembly according to claim 2, wherein the noise reduction mounting member comprises:
a vibration damper arranged between the fan guard and the fan body, and the vibration damper is fixed on the fan bracket; and
a fastener configured to connect the fan guard, the vibration damper and the fan body with each other.

4. The fan assembly according to claim 3, wherein the vibration damper comprises:
a vibration damping pad fixed on the fan bracket, wherein a through hole is provided in the vibration damping pad;
a bushing arranged in the through hole of the vibration damping pad; and
a gasket arranged on the bushing, wherein the fastener passes through the fan guard, the gasket, the bushing and the fan body successively to connect the fan guard, the gasket, the bushing and the fan body with each other.

5. The fan assembly according to claim 4, wherein a clamping groove is circumferentially provided on an outer periphery of the vibration damping pad, and the fan bracket is clamped and fixed in the clamping groove.

6. The fan assembly according to claim 4, wherein the vibration damping pad is a rubber pad or a spring.

7. The fan assembly according to claim 3, wherein a height of the vibration damper is greater than or equal to 10 mm.

8. The fan assembly according to claim 3, wherein the noise reduction mounting member further comprises:
a nut screwed on the fastener and abutting against the fan body.

9. The fan assembly according to claim 1, wherein the fan body is integrally formed with the noise reduction mounting member.

10. The fan assembly according to claim 1, wherein a plurality of noise reduction mounting members are provided, and the plurality of noise reduction mounting members are arranged spaced apart along a circumferential direction of the fan body.

11. The fan assembly according to claim 2, wherein a plurality of fan bodies are provided, and the plurality of fan bodies are arranged spaced apart on the fan bracket.

12. An inverter, comprising the fan assembly according to claim 1.

13. The inverter according to claim 12, further comprising:
a box; and
heat dissipation fins arranged on the box, wherein the fan assembly is arranged to directly face the heat dissipation fins, and the fan assembly is configured to dissipate heat for the heat dissipation fins.
